(19) United States
(12) Patent Application Publication
(10) Pub. No.: US 2014/0085826 A1
(43) Pub. Date: Mar. 27, 2014

(54) ELECTRONIC DEVICE AND PLUG AND PLAY UNIT THEREOF

(71) Applicant: Wistron NeWeb Corp., Hsinchu (TW)

(72) Inventors: Che Cheng WU, Hsinchu (TW); Chien Ming PENG, Hsinchu (TW); Chi Te LIN, Hsinchu (TW); CHI MING LU, Hsinchu (TW)

(21) Appl. No.: 13/942,124

(22) Filed: Jul. 15, 2013

(30) Foreign Application Priority Data
Sep. 21, 2012 (TW) 101134629

(51) Int. Cl. H05K 7/20

(52) U.S. Cl. CPC H05K 7/20509
USPC 361/704

(57) ABSTRACT

A plug and play unit is provided. The plug and play unit includes a unit housing, a joint, a substrate and a heat conductive member. The joint is connected to the unit housing. The substrate is disposed in the unit housing and the joint, wherein the substrate includes a heat conductive layer and a USB connection port. The heat conductive member thermally connects the joint to the heat conductive layer to transmit heat from the heat conductive layer to the joint.

### CROSS REFERENCE TO RELATED APPLICATIONS

This Application claims priority of Taiwan Patent Application No. 101134629, filed on Sep. 21, 2012, the entirety of which is incorporated by reference herein.

### BACKGROUND OF THE INVENTION

1. Field of the Invention

The present invention relates to a plug and play unit, and in particular, relates to a plug and play unit utilized to transmit wireless signals.

2. Description of the Related Art

The dimensions of USB devices have gradually decreased, and the structures thereof have been simplified. Meanwhile, the operation speed and power of chips (for example, wireless network chips) of the USB device have increased, and the heat generated by the chips have increased. Conventional USB devices utilize plastic housings or metal housings. When heat is transmitted to the housing of the USB device from chips, the housing may overheat, and users may be burnt from the housing.

### BRIEF SUMMARY OF THE INVENTION

In one embodiment of the invention, a plug and play unit is provided. The plug and play unit includes a unit housing, a joint, a substrate and a heat conductive member. The joint is connected to the unit housing. The substrate is disposed in the unit housing and the joint, wherein the substrate includes heat conductive layer and a USB connection port. The heat conductive member thermally connects the joint to the heat conductive layer to transmit heat from the heat conductive layer to the joint.

Utilizing the plug and play unit of the embodiments of the invention, the heat on the substrate is transmitted to the joint via the heat conductive layer, the heat conductive pad and the heat conductive member, and is transmitted to an electronic device (for example, notebook) which the plug and play unit plugs into via the joint. Therefore, the heat of the plug and play unit is dissipated rapidly, and the plug and play unit is prevented from overheating.

In another embodiment of the invention, an antenna ground portion of the plug and play unit is electrically connected to a device housing or a ground layer of a mainboard of the electronic device. The antenna grounding area is increased, and the transmission of the transmission module is improved.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A and 1B are perspective views of the plug and play unit of a first embodiment of the invention;

FIG. 1C is an exploded view of the plug and play unit of the first embodiment of the invention;

FIG. 1D is a sectional view along direction 1D-1D′ of FIG. 1B;

FIG. 2A shows the plug and play unit of the second embodiment of the invention;

FIG. 2B is a sectional view along direction 2B-2B′ of FIG. 2A;

FIG. 3A shows the plug and play unit of the third embodiment of the invention;

FIG. 3B is a sectional view along direction 3B-3B′ of FIG. 3A;

FIG. 4A shows the plug and play unit of the fourth embodiment of the invention;

FIG. 4B is a sectional view along direction 4B-4B′ of FIG. 4A;

FIGS. 5A and 5B show the plug and play units of the fifth embodiment of the invention;

FIG. 6 shows the plug and play unit of the sixth embodiment of the invention;

FIG. 7 shows the plug and play unit of the embodiment of the invention plugging into the electronic device; and

FIG. 8 is a block diagram of the plug and play unit and the electronic device of the embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

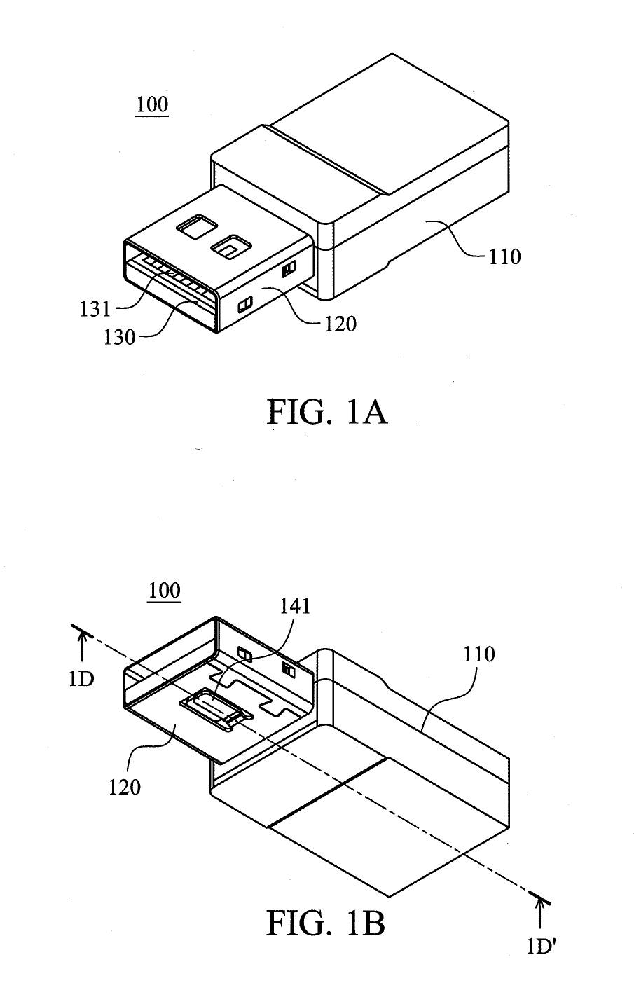

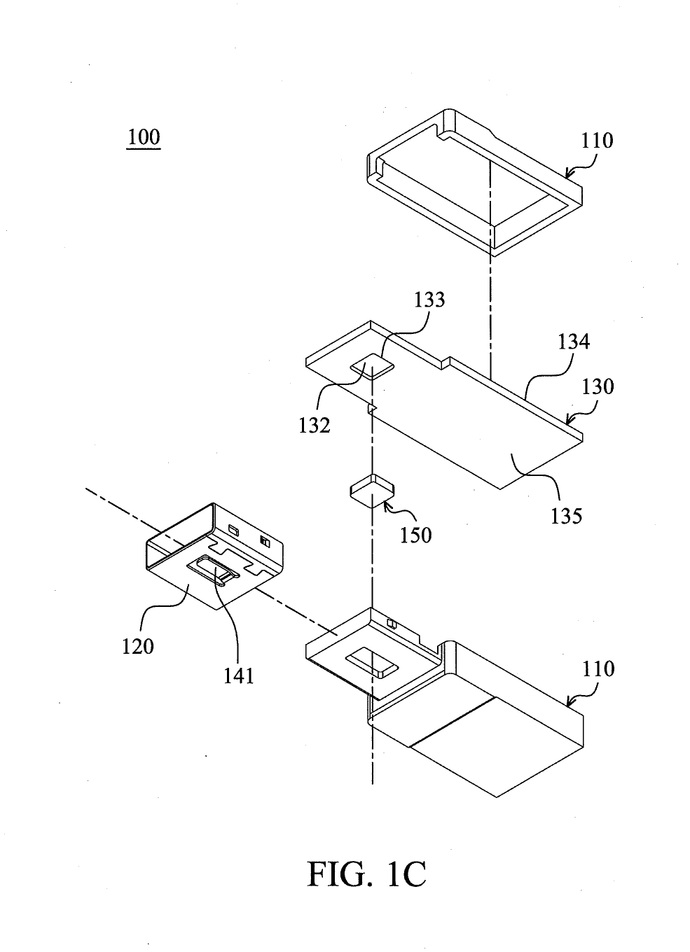

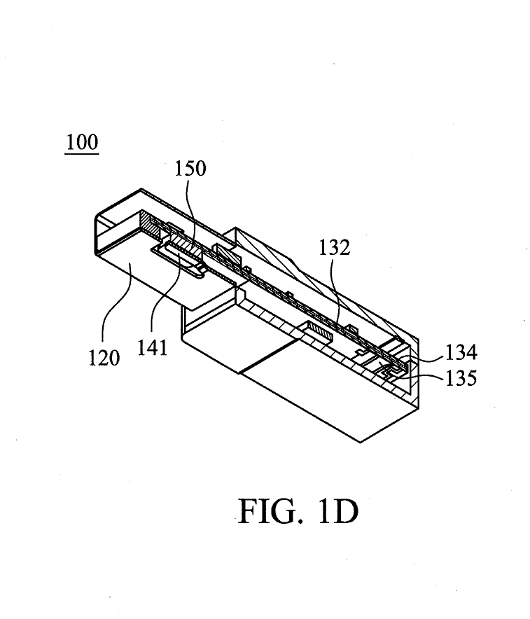

With reference to FIGS. 1A, 1B and 1C, FIGS. 1A and 1B are perspective views of the plug and play unit of a first embodiment of the invention, and FIG. 1C is an exploded view of the plug and play unit of the first embodiment of the invention. The plug and play unit 100 of the first embodiment of the invention comprises a unit housing 110, a joint 120, a substrate 130 and a heat conductive member 141. The joint 120 is connected to the unit housing 110. The substrate 130 is disposed in the unit housing 110 and the joint 120, wherein the substrate 130 comprises a USB connection port 131.

FIG. 1D is a sectional view along direction 1D-1D′ of FIG. 1B. With reference to FIGS. 1B, 1C and 1D, the substrate 130 comprises a heat conductive layer 132. In this embodiment, the heat conductive layer 132 is embedded in the substrate 130. In a modified example, the position of the heat conductive layer 132 can be modified. An open window 133 is formed on a surface of the substrate 130, and the heat conductive layer 132 is exposed in the window 133 (FIG. 1C). In this embodiment, the substrate 130 comprises a first surface 134 and a second surface 135, wherein the first surface 134 is opposite to the second surface 135, the USB connection port 131 is disposed on the first surface 134 (with reference to FIG. 1A), and the window 133 is formed on the second surface 135. In this embodiment, the window 133 corresponds to the USB connection port 131.

With reference to FIGS. 1C and 1D, the plug and play unit 100 of the first embodiment of the invention further comprises a heat conductive pad 150, and the heat conductive pad 150 is disposed in the window 133 and contacts the heat conductive layer 132. The heat conductive member 141 contacts the heat conductive pad 150. Therefore, the heat conductive member 141 thermally connects the joint 120 to the heat conductive layer 132. The heat generated by the electronic elements (for example, wireless network chip) of the substrate 130 is transmitted to the joint 120 via the heat conductive layer 132, the heat conductive pad 150 and the heat conductive member 141. In this embodiment, the heat conductive member 141 is integrally formed on the joint 120.

Utilizing the plug and play unit of this embodiments of the invention, the heat on the substrate is transmitted to the joint via the heat conductive layer, the heat conductive pad and the heat conductive member, and is transmitted to an electronic device (for example, notebook) which the plug and play unit plugs into via the joint. Therefore, the heat of the plug and play unit is dissipated rapidly, and the plug and play unit is prevented from overheated.

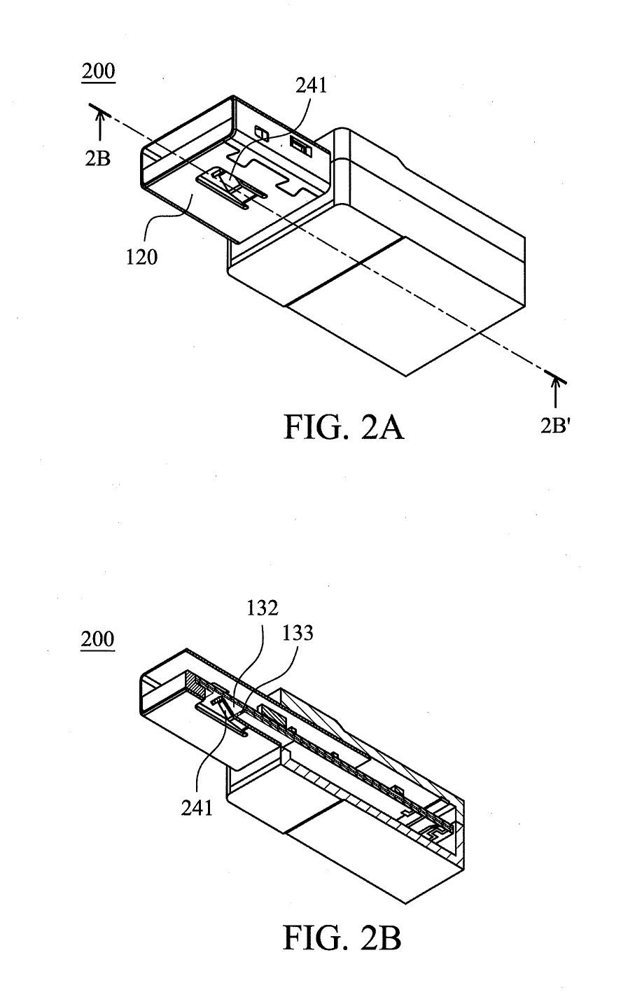

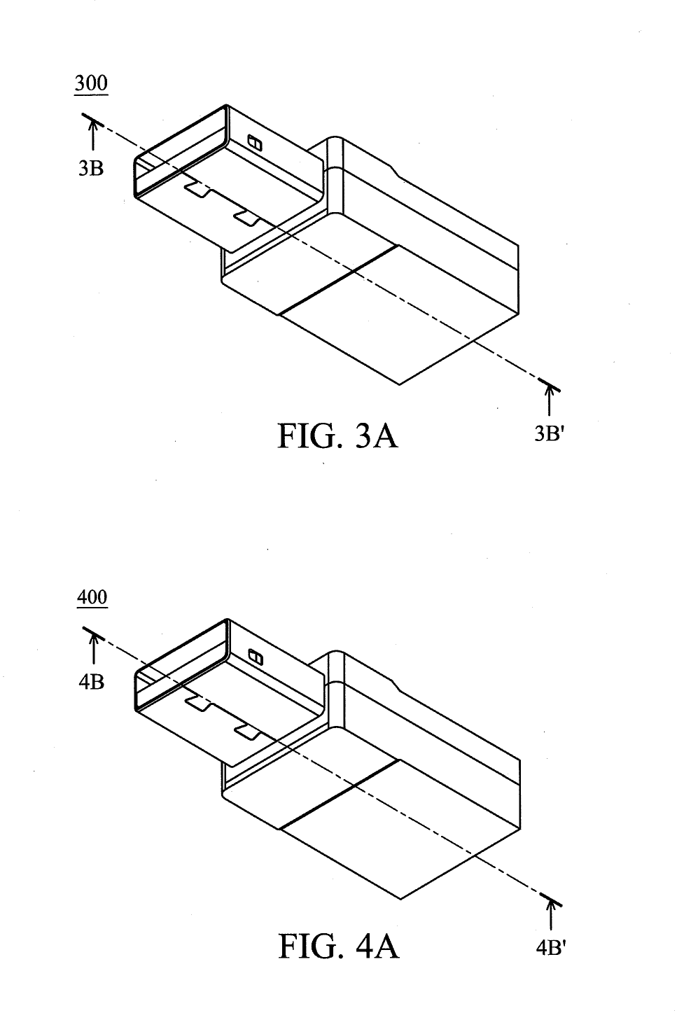

FIG. 2A shows a plug and play unit 200 of a second embodiment of the invention, and FIG. 2B is a sectional view along direction 2B-2B′ of FIG. 2A. With reference to FIG. 2A and 2B, in the second embodiment, the heat conductive pad is omitted. The heat conductive member 241 is integrally formed on the joint 120, and directly contacts the heat conductive layer 132 in the window 133.

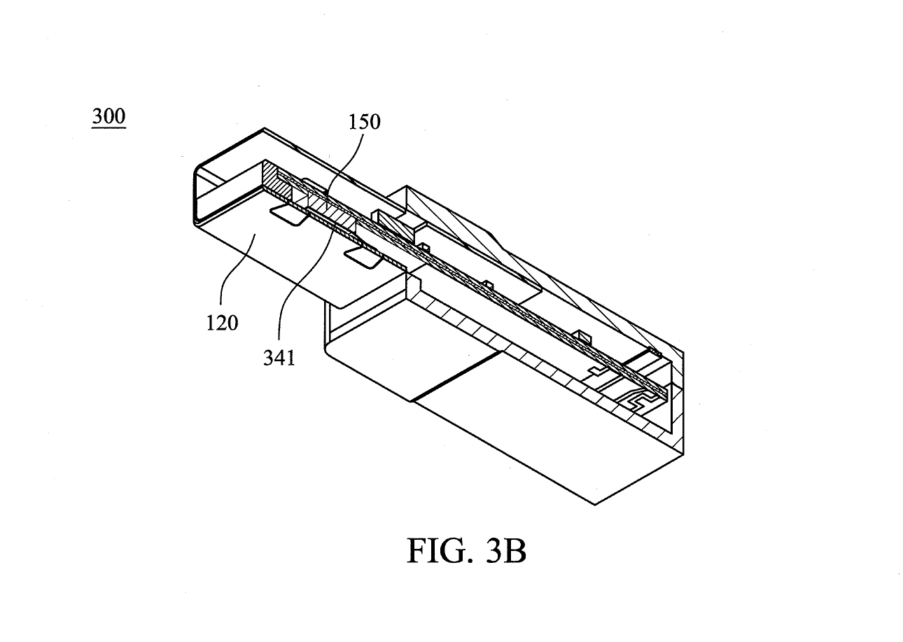

FIG. 3A shows a plug and play unit 300 of a third embodiment of the invention, and FIG. 3B is a sectional view along direction 3B-3B′ of FIG. 3A. With reference to FIG. 3A and 3B, in the third embodiment, an end of the heat conductive member 341 is welded to the heat conductive pad 150, and the other end of the conductive member 341 contacts the joint 120.

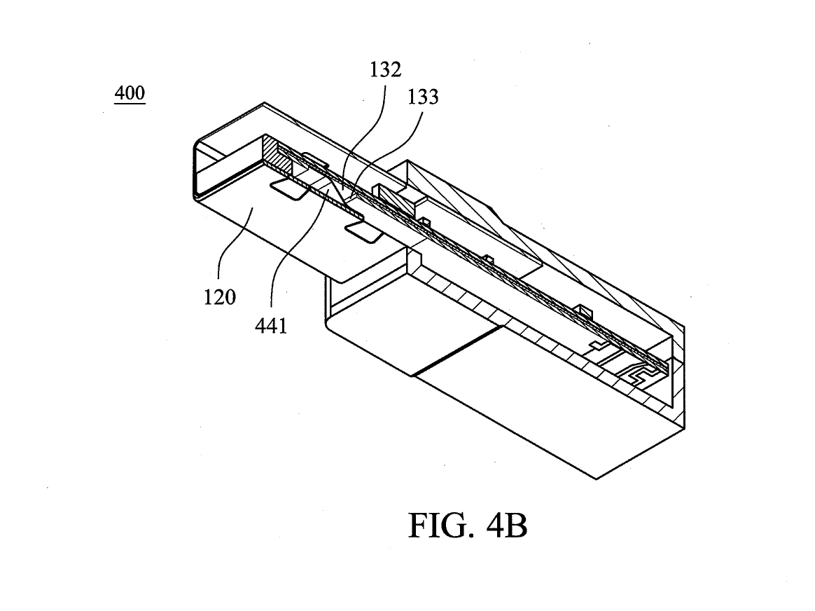

FIG. 4A shows a plug and play unit 400 of a fourth embodiment of the invention, and FIG. 4B is a sectional view along direction 4B-4B′ of FIG. 4A. With reference to FIG. 4A and 4B, in the fourth embodiment, the heat conductive pad is omitted. An end of the heat conductive member 441 is welded to the heat conductive layer 132 in the window 133, and the other end of the conductive member 441 contacts the joint 120.

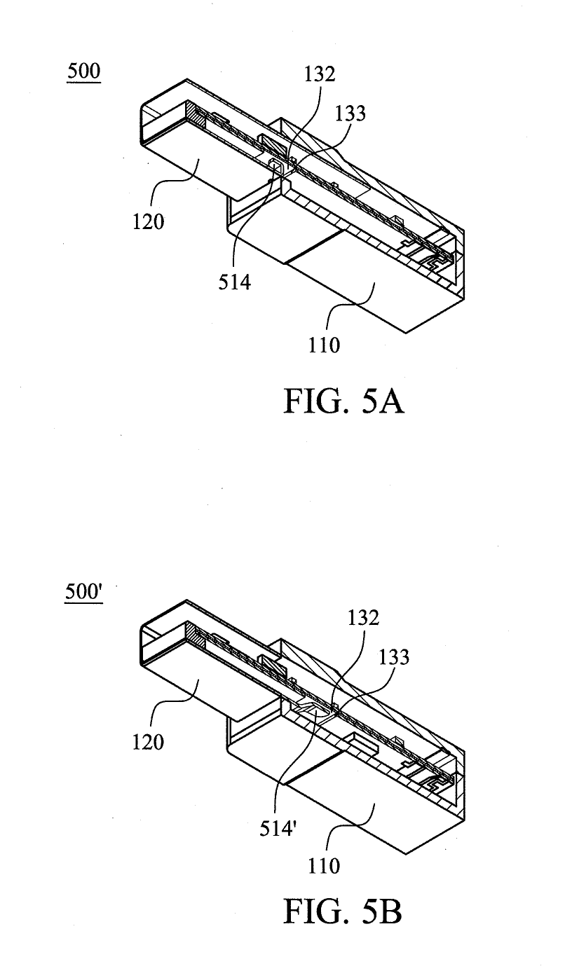

FIGS. 5A and 5B show a plug and play unit 500 and a plug and play unit 500′ of a fifth embodiment of the invention. In the fifth embodiment of the invention, the window 133 is not inevitable corresponding to the USB connection port. The window 133 can be formed on the location where the joint 120 connects the unit housing 110 (FIG. 5A), or formed in the unit housing 110 (FIG. 5B). The joint 120 is thermally connected to the heat conductive layer 132 via the heat conductive member 541 or the heat conductive member 541′.

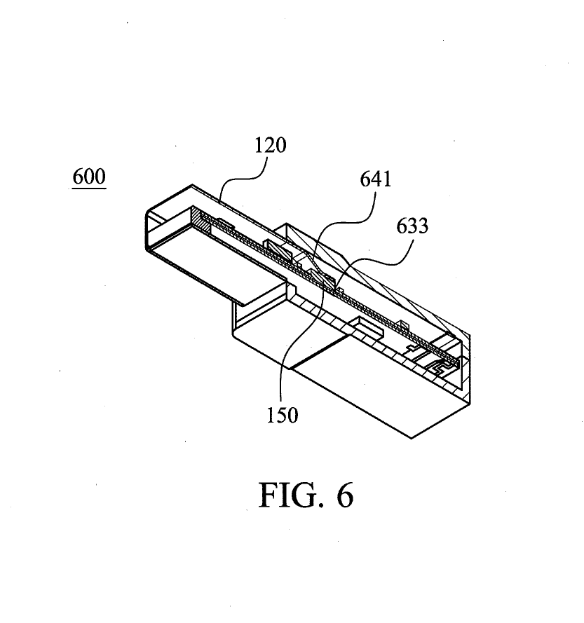

FIG. 6 shows a plug and play unit 600 of a sixth embodiment of the invention. In the sixth embodiment of the invention, the USB connection port and the window 633 are disposed on the first surface, and the heat conductive pad 150 is disposed in the window 633, and the heat conductive member 641 contacts the heat conductive pad 150 to transmit heat, and the heat conductive member 641 is integrally formed on the joint 120. In a modified embodiment, the heat conductive pad can be omitted. In another modified embodiments, the heat conductive member 641 is welded to the heat conductive pad 150 or is directly welded to the heat conductive layer 132 in the window 633.

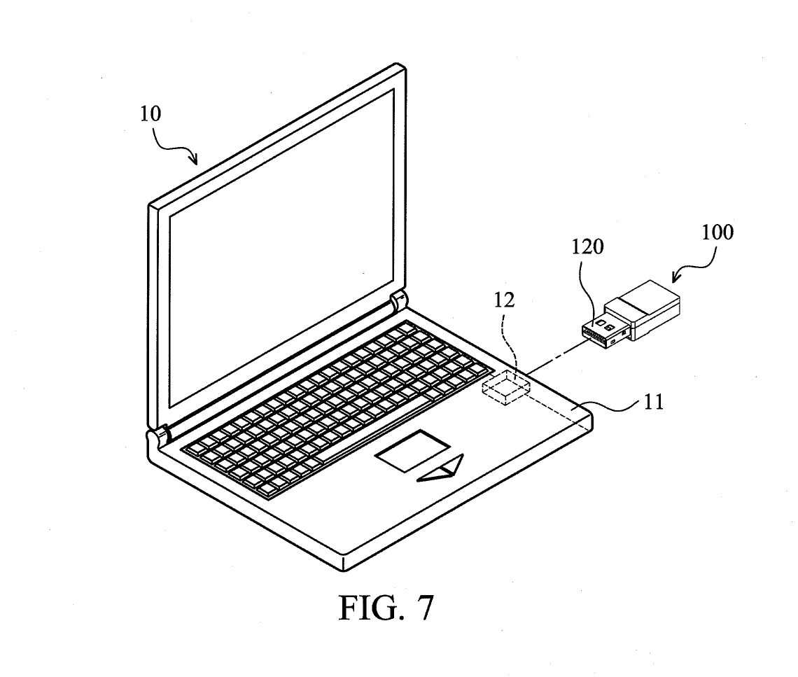

FIG. 7 shows the plug and play unit 100 of the embodiment of the invention plugging to an electronic device 10. The electronic device 10 comprises a device housing 11 and a USB connection socket 12. The USB connection socket 12 is disposed in the device housing 11. In a modified embodiment, the device housing 11 is made of metal, and the USB connection socket 12 is connected to the device housing 11. The joint 120 is connected to the USB connection socket 12, and the joint 120 is thermally connected to the device housing 11. The heat on the substrate of the plug and play unit 100 can be transmitted to the device housing via the heat conductive layer and the joint, and is dissipated rapidly.

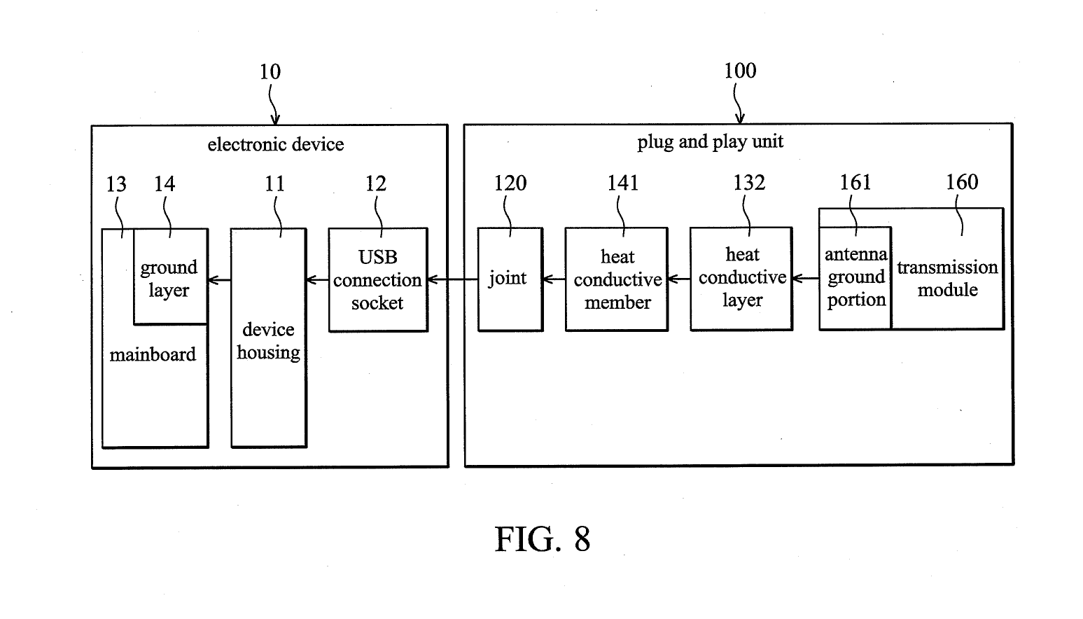

FIG. 8 is a block diagram of the plug and play unit 100 and the electronic device 10 of an embodiment of the invention, wherein the plug and play unit 100 further comprises a transmission module 160, and the transmission module 160 is formed on the substrate 130, and the transmission module 160 comprises an antenna ground portion 161. The heat conductive layer 132 is electrically connected to the antenna ground portion 161, the joint 120 is electrically connected to the heat conductive layer 132 via the heat conductive member 141, and the joint 120 is electrically connected to the device housing 11 via the USB connection socket 12, and the device housing 11 is thereby electrically connected to the antenna ground portion 161.

The electronic device 10 comprises a mainboard 13, wherein the mainboard 13 comprises a ground layer 14. In one embodiment, the ground layer 14 is electrically connected to the device housing 11, and therefore electrically connected to the antenna ground portion 161.

In the embodiment above, the antenna ground portion 161 of the plug and play unit 100 is electrically connected to the device housing 11 or the ground layer 14 of the mainboard 13 of the electronic device 10. The antenna grounding area is increased, and the transmission of the transmission module is improved.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A plug and play unit, comprising:
a unit housing;
a joint, connected to the unit housing;
a substrate, disposed in the unit housing and the joint, wherein the substrate comprises a heat conductive layer and a USB connection port; and
a heat conductive member, thermally connecting the joint to the heat conductive layer to transmit heat from the heat conductive layer to the joint.

2. The plug and play unit as claimed in claim 1, wherein the heat conductive layer is embedded in the substrate.

3. The plug and play unit as claimed in claim 2, wherein the substrate has an open window, and the heat conductive layer is exposed in the window.

4. The plug and play unit as claimed in claim 3, wherein the substrate comprises a first surface and a second surface, the first surface is opposite to the second surface, the USB connection port is disposed on the first surface, and the window is formed on the second surface.

5. The plug and play unit as claimed in claim 4, wherein the window corresponds to the USB connection port.

6. The plug and play unit as claimed in claim 4, further comprising a heat conductive pad, wherein the heat conductive pad is disposed in the window and contacts the heat conductive layer, and the heat conductive member contacts the heat conductive pad.

7. The plug and play unit as claimed in claim 6, wherein the heat conductive member is welded to the heat conductive pad.

8. The plug and play unit as claimed in claim 3, wherein the substrate comprises a first surface, and the USB connection port and the window are formed on the first surface.

9. The plug and play unit as claimed in claim 8, further comprising a heat conductive pad, wherein the heat conductive pad is disposed in the window and contacts the heat conductive layer, and the heat conductive member contacts the heat conductive pad.

10. The plug and play unit as claimed in claim 9, wherein the heat conductive member is welded to the heat conductive pad.

11. The plug and play unit as claimed in claim 1, wherein the heat conductive member is integrally formed on the joint.

12. The plug and play unit as claimed in claim 1, further comprising a transmission module, wherein the transmission module is formed on the substrate, and the transmission module comprises an antenna ground portion.

13. The plug and play unit as claimed in claim 12, wherein the heat conductive layer is electrically connected to the antenna ground portion, and the joint is electrically connected to the heat conductive layer via the heat conductive member.

14. An electronic device, comprising:
a device housing;
a USB connection socket, disposed in the device housing and connected to the device housing; and
the plug and play unit as claimed in claim 1, wherein the joint is connected to the USB connection socket, and the joint is thermally connected to the device housing.

15. The electronic device as claimed in claim 14, wherein the device housing is made of metal.

16. The electronic device as claimed in claim 15, wherein the plug and play unit further comprises a transmission module, and the transmission module is formed on the substrate, and the transmission module comprises an antenna ground portion.

17. The electronic device as claimed in claim 16, wherein the heat conductive layer is electrically connected to the antenna ground portion, the joint is electrically connected to the heat conductive layer via the heat conductive member, the joint is electrically connected to the device housing, and the device housing is thereby electrically connected to the antenna ground portion.

18. The electronic device as claimed in claim 17, further comprising a mainboard, wherein the mainboard comprises a ground layer, and the ground layer is electrically connected to the device housing.
